(19) United States
(12) Patent Application Publication
(10) Pub. No.: US 2014/0335679 A1
(43) Pub. Date: Nov. 13, 2014

(54) METHODS FOR ETCHING A SUBSTRATE

(71) Applicant: Applied Materials, Inc., Santa Clara, CA (US)

(72) Inventors: TONG LIU, San Jose, CA (US); DAVID REYLAND, San Francisco, CA (US); ROHIT MISHRA, Santa Clara, CA (US); KHALID MOHIUDDIN SIRAJUDDIN, San Jose, CA (US); MADHAVA RAO YALAMANCHILI, Morgan Hill, CA (US); AJAY KUMAR, Cupertino, CA (US)

(21) Appl. No.: 13/938,186

(22) Filed: Jul. 9, 2013

Related U.S. Application Data
(60) Provisional application No. 61/821,464, filed on May 9, 2013.

(51) Int. Cl. H01L 21/3065; H01L 21/308

(52) U.S. Cl. CPC H01L 21/3065; H01L 21/308
USPC 438/466; 438/714

(57) ABSTRACT

In some embodiments, a method for etching features into a substrate may include exposing a substrate having a photoresist layer disposed atop the substrate to a first process gas to form a polymer containing layer atop sidewalls and a bottom of a feature formed in the photoresist layer, wherein the first process gas is selectively provided to a first area of the substrate via a first set of gas nozzles disposed within a process chamber and; exposing the substrate to a second process gas having substantially no oxygen to etch the feature into the substrate, wherein the second process gas is selectively provided to a second area of the substrate via a second set of gas nozzles disposed in the process chamber.

### CROSS-REFERENCE TO RELATED APPLICATIONS

This application claims benefit of U.S. provisional patent application Ser. No. 61/821,464, filed May 9, 2013, which is herein incorporated by reference in its entirety.

### FIELD

Embodiments of the present invention generally relate to semiconductor device fabrication.

### BACKGROUND

During conventional etch processes utilizing photoresist layers to define features, the photoresist layers are often partially consumed as the substrate is etched. However, the inventors have observed that due to a substrate to photoresist layer etch selectivity typically achieved in conventional processes, the photoresist layer may be substantially or completely consumed before reaching a desired etch depth, thereby limiting the depth of the features that can be formed. To offset such selectivity, the thickness of the photoresist layer may be increased. However, increasing the thickness of the photoresist layer leads to higher production costs and a diminished control of photoresist consumption uniformity and, therefore, non-uniformity of the etched features.

Therefore, the inventors have provided improved methods for etching a substrate.

### SUMMARY

Methods for etching a substrate are provided herein. In some embodiments, a method for etching features into a substrate may include exposing a substrate having a photoresist layer disposed atop the substrate to a first process gas to form a polymer containing layer atop sidewalls and a bottom of a feature formed in the photoresist layer, wherein the first process gas is selectively provided to a first area of the substrate via a first set of gas nozzles disposed within a process chamber and; exposing the substrate to a second process gas to etch the feature into the substrate, wherein the second process gas is selectively provided to a second area of the substrate via a second set of gas nozzles disposed in the process chamber.

In some embodiments, a computer readable medium is provided, having instructions stored thereon that, when executed, cause a method for etching features into a substrate to be performed. The method may include exposing a substrate having a photoresist layer disposed atop the substrate to a first process gas to form a polymer containing layer atop sidewalls and a bottom of a feature formed in the photoresist layer, wherein the first process gas is selectively provided to a first area of the substrate via a first set of gas nozzles disposed within a process chamber and; exposing the substrate to a second process gas to etch the feature into the substrate, wherein the second process gas is selectively provided to a second area of the substrate via a second set of gas nozzles disposed in the process chamber.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a method for etching a substrate in accordance with some embodiments of the present invention.

FIGS. 2A-C depict a substrate through various stages of a method for etching a substrate in accordance with some embodiments of the present invention.

FIG. 3 depicts a process chamber suitable to perform a method for etching a substrate in accordance with some embodiments of the present invention.

FIG. 4 depicts a gas ring suitable for use in a process chamber to perform a method for etching a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods for etching a substrate are disclosed herein. In at least some embodiments, the inventive methods may advantageously provide a method of etching features in a substrate that provides for increased silicon to photoresist layer etch selectivity, thereby allowing features having an increased depth to be formed while decreasing consumption of the photoresist layer during the etch process. While not limiting, in some embodiments, the inventive methods may be utilized to form high aspect ratio features (e.g., a feature having a side wall to bottom ratio of greater than about 4:1) or through silicon via (TSV) features.

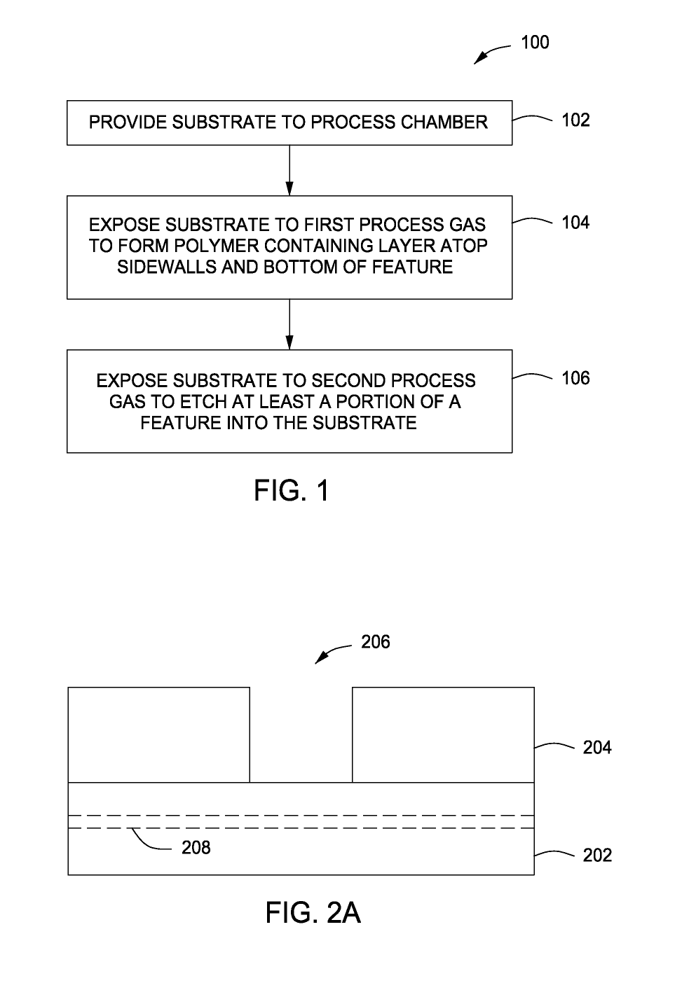

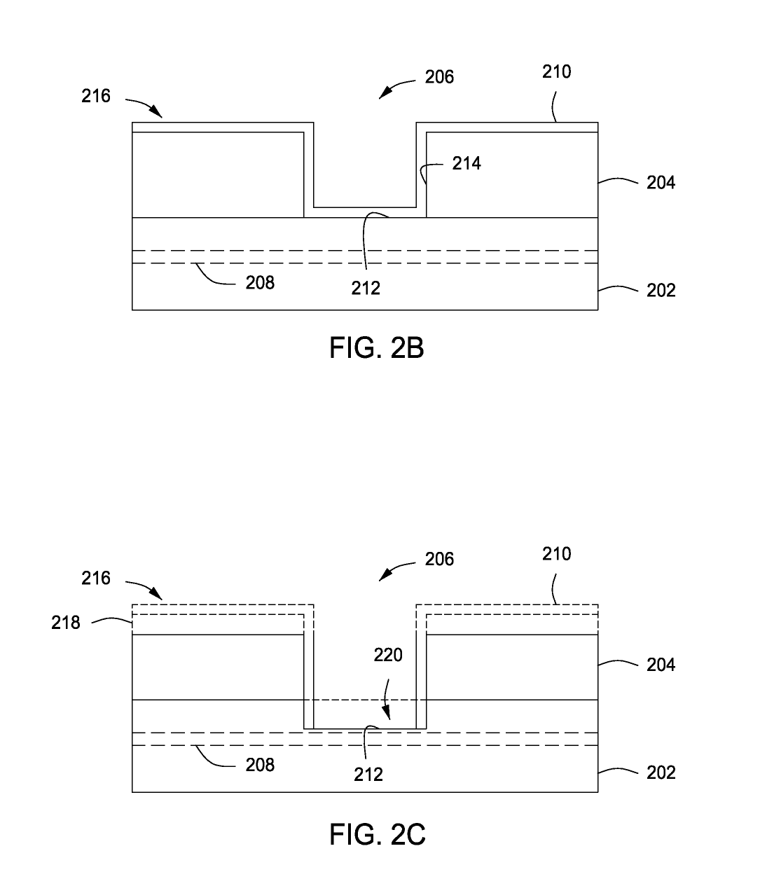

FIG. 1 depicts a method 100 for etching a substrate in accordance with some embodiments of the present invention. FIGS. 2A-2C depict a substrate through various stages of the method 100 in accordance with some embodiments of the present invention.

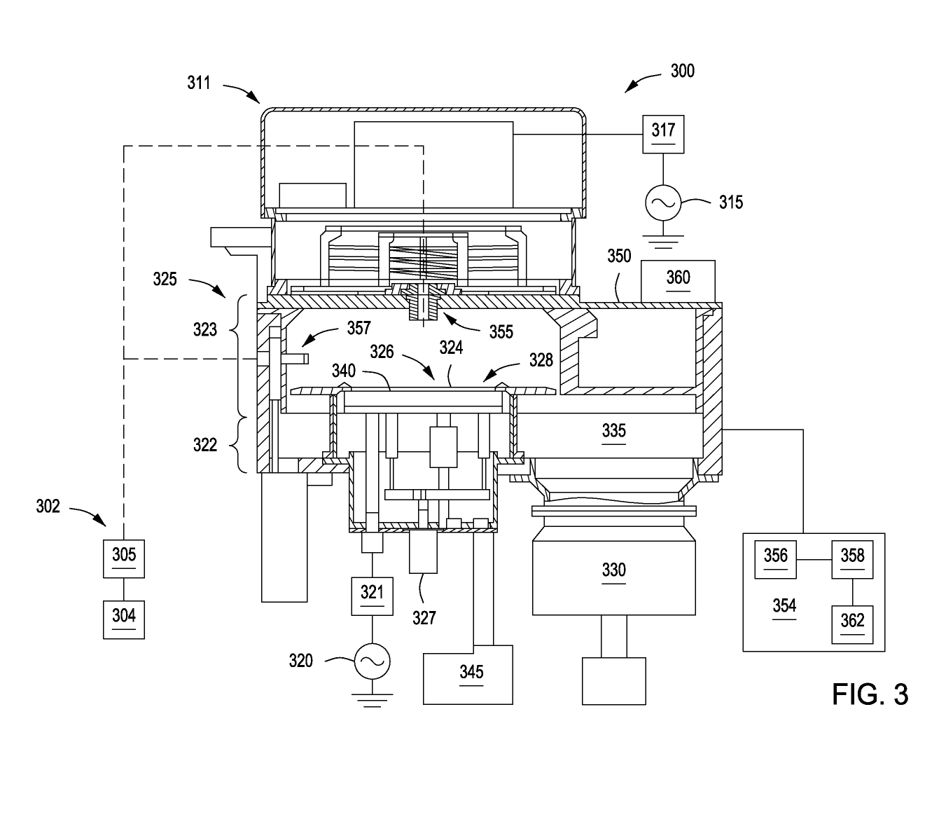

The method 100 begins at 102, where a substrate 202 is provided to a process chamber. The process chamber may be any type of process chamber suitable to etch one or more features in a substrate (e.g., substrate 202), for example, an etch chamber (e.g., process chamber), such as described below with respect to FIG. 3.

The substrate may be any type of substrate suitable for semiconductor device fabrication. For example, referring to FIG. 2, the substrate 202 may be a silicon substrate, for example crystalline silicon (e.g., Si<100> or Si<111>), silicon oxide, strained silicon, doped or undoped polysilicon, or the like, a III-V or II-VI compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like.

In some embodiments, the substrate 202 may comprise a partially or fully fabricated semiconductor device, for example such as a two dimensional or three dimensional device, such as a multigate device, fin field effect transistor (FinFET), metal oxide semiconductor field effect transistor (MOSFET), nanowire field effect transistor (NWFET), tri-gate transistor, a memory device such as a NAND device or NOR device, or the like.

In some embodiments, the substrate includes one or more layers, for example, a tunnel oxide layer 208, such as shown in FIGS. 2A-C. The tunnel oxide layer 208 may comprise any materials suitable for the fabrication of a desired semiconductor device. For example, in some embodiments, the tunnel oxide layer 208 may include silicon and oxygen, such as silicon oxide (SiO₂), silicon oxynitride (SiON), or high-k dielectric materials, such as aluminum (Al), hafninm (Hf), orlanthanum (La), zirconium (Zr) based oxides or oxynitrides, or silicon nitrides (SiₓN_{y}), in single or layered structures, or the like.

In some embodiments, the substrate may include a plurality of field isolation regions (not shown) formed in the substrate 202 to isolate wells having different conductivity types (e.g., n-type or p-type) and/or to isolate adjacent transistors (not shown). The field isolation regions may be shallow trench isolation (STI) structures formed, for example, by etching a trench into the substrate 202 and then filling the trench with a suitable insulator, such as silicon oxide (SiO₂), silicon oxynitride (SiON), or the like.

In some embodiments, a photoresist layer 204 having a feature 206 to be formed in the substrate 202 is disposed atop the substrate 202. The photoresist layer 204 may comprise any suitable photoresist, such as a positive or negative photoresist that may be formed and patterned in any suitable manner, for example, via optical lithography techniques using light types such as i-line (e.g., about 365 nm wavelength), g-line (e.g., about 436 nm wavelength), ultraviolet (UV), deep ultraviolet (DUV) or extreme ultraviolet (EUV), contact printing techniques, or the like.

Next, at 104, the substrate 202 is exposed to a first process gas to form a polymer containing layer 210 atop the sidewalls 214 and bottom 212 of the feature 206, such as shown in FIG. 2B. In addition, in some embodiments, the polymer containing layer 210 may be formed atop at least a portion of the photoresist layer 204 (shown at 216). The inventors have observed that forming the polymer containing layer 210 protects the photoresist layer 204, thereby reducing an amount of the photoresist etched during a subsequent etch process (e.g., the etch process described below). Reducing the amount of photoresist etched increases the etch selectivity of the substrate 202 during the etch process, thereby allowing for features to be etched to a deeper depth without consuming the photoresist.

The polymer containing layer 210 may comprise any process compatible polymer containing material suitable to protect the photoresist 204 as described above. For example, in some embodiments, the polymer containing layer may comprise fluorocarbons (CₓF_{y}), hydrofluorocarbons (CₓH_{y}F_{z}), or the like. In some embodiments, the polymer containing layer 210 may be dependent on the composition or type of substrate 202, process conditions, or the like.

In some embodiments, the polymer containing layer 210 may be formed having varying thicknesses. For example, in some embodiments, a thickness of the polymer containing layer 210 formed on the bottom 212 of the feature 206 (a first thickness) may be less than a thickness of the polymer containing layer 210 formed on the sidewalls 214 of the feature 206 (a second thickness). For example, in some embodiments, a ratio of the thickness of the polymer containing layer 210 formed on the sidewalls 214 of the feature 206 to a thickness of the polymer containing layer 210 on the bottom 212 of the feature 206 may be greater than about 2:1. The inventors have observed that providing a greater thickness of the polymer containing layer 210 on the sidewalls 214 of the feature 206 allows for the polymer containing layer 210 formed on the bottom 212 of the feature 206 to be consumed completely while the polymer containing layer 210 on the sidewalls 214 remain, thereby reducing an amount of lateral etching of the feature 206 during the etch process, and thereby providing an increased vertical etch of the feature.

In some embodiments, the first process gas may be selectively provided to a first area of the substrate 202 via a first set of gas inlets disposed within the process chamber (e.g., gas nozzles 355, 357 described below). The first area may be any portion of the substrate 202, for example, an edge of the substrate 202 (e.g., the edge 328 of the substrate 324 as shown in FIG. 3), the center of the substrate 202 (e.g., the center of the substrate 326 as shown in FIG. 3), or the like. Alternatively, or in combination, in some embodiments, the first process gas may be provided to a plurality of first areas sequentially. For example, the first process gas may be provided to an area proximate the edge of the substrate 202 and then subsequently provided to an area proximate the center of the substrate 202. The first process gas may be provided to each of the first plurality of areas for any amount of time, for example such as about 350 milliseconds to about 5 seconds. The first process gas may be provided to the plurality of first areas cyclically for as many cycles suitable to form the desired polymer containing layer 210.

The inventors have observed that selectively providing the first process gas as described above may advantageously provide uniformity of the polymer containing layer 210 across the substrate. The first process gas may be selectively provided to the first area or plurality of first areas of the substrate 202 via any suitable mechanism or hardware configuration, for example such as a gas distribution apparatus configured to provide selective directional flow and selective proportioning of the first process gas, such as the fast gas exchange unit and/or the gas ring 400 described below.

The first process gas may comprise any polymer forming gas suitable to form the polymer containing layer 210. For example, in some embodiments, the first process gas may comprise a fluorine-containing gas, a fluorocarbon-containing gas or hydrofluorocarbon-containing gas as the primary reactive agent. For example, in embodiments where the process gas comprises a fluorine-containing gas, the fluorine-containing gas may comprise gases that can be dissociated to form fluorine radicals, such as NF₃, SF₆, or the like. In embodiments where the process gas comprises a fluorocarbon-containing gas such as CF₄, C₄F₆, C₄F₈, or the like, the fluorocarbon-containing gas may comprise gases that dissociate to form fluorine radicals and CFₓ (where x is a positive integer). In embodiments where the process gas comprises a hydrofluorocarbon-containing gas such as CH₂F₂, CH₄, CHF₃, or the like, the hydrofluorocarbon-containing gas may comprise gases that dissociate to form F radicals and CFₓ, as well as that provides hydrogen (H) that combines with the free fluorine to increase a C:F ratio (or C:H:F ratio). In some embodiments the first process gas may include an inert gas, such as one or more of argon (Ar), neon (Ne), or the like to facilitate delivering the first process gas to the process chamber.

The first process gas may be provided at any flow rate suitable to facilitate forming the polymer containing layer 210. For example, in some embodiments, the first process gas may be provided at a flow rate of about 200 to about 800 sccm. The first process gas may be provided to the process chamber for any period of time, for example, such as up to about 2 seconds, or in some embodiments, about 1 second to about 2 seconds.

In some embodiments, the first process gas may be ignited to form plasma to facilitate forming the polymer containing layer 210. For example, in some embodiments, an RF and/or DC power may be provided to the process chamber to ignite the first process gas to form and maintain the plasma. In embodiments where an RF power is provided, about 1000 W to about 5000 W of RF power may be provided.

In addition, one or more process parameters, for example, such as a temperature or pressure within the process chamber, may be adjusted to facilitate depositing the polymer containing layer 210 having the desired characteristics (e.g., density, thickness, composition, or the like). For example, in some embodiments, the process chamber may be maintained at a pressure of about 100 to about 200 mTorr. In some embodiments, the process chamber may be maintained at about 10 to about 30 degrees Celsius. In some embodiments, a bias power may be applied to an electrode or substrate support within the process chamber to facilitate depositing the polymer containing layer 210. In such embodiments, about 0 to about 100 W of bias power may be provided to the electrode or substrate support. In some embodiments, the bias power may be provided continuously or, in some embodiments, pulsed.

Next, at 106, the substrate 202 is exposed to a second process gas to etch at least a portion of a feature 220 into the substrate 202, for example, such as shown in FIG. 2C. In some embodiments, as the substrate 202 is etched a portion of the photoresist layer (shown at 218) and/or a portion of the polymer containing layer (shown at 222) may be also etched or removed.

In some embodiments, the second process gas may be selectively provided to a second area of the substrate 202 via a first set of gas inlets disposed within the process chamber (e.g., gas nozzles 355, 357 described below). The second area may be any portion of the substrate 202, for example, an edge of the substrate 202 (e.g., the edge 328 of the substrate 324 as shown in FIG. 3), the center of the substrate 202 (e.g., the center of the substrate 326 as shown in FIG. 3), or the like. The second area may be the same as, different from, or an overlapping at least a portion of, the first area.

Alternatively, or in combination, in some embodiments, the second process gas may be provided to a plurality of second areas sequentially. For example, the second process gas may be provided to an area proximate the edge of the substrate 202 and then subsequently provided to an area proximate the center of the substrate 202. The second process gas may be provided to each of the second plurality of areas for any amount of time, for example such as about 350 milliseconds to about 5 seconds. The second process gas may be provided to the plurality of second areas cyclically for as many cycles suitable to form the desired polymer containing layer 210.

The inventors have observed that selectively providing the second process gas as described above may advantageously provide greater etch uniformity across the substrate 202. The second process gas may be selectively provided to the second area of the substrate 202 via, for example, the mechanisms or hardware configurations such as described above with respect to the first process gas.

The second process gas may comprise any process gas suitable to etch the substrate 202 to form the feature 220. For example, in some embodiments, the second process gas may comprise a fluorine-containing gas, for example, such as sulfur hexafluoride (SF₆), carbon tetrafluoride (CF₄), nitrogen trifluoride (NF₃). In some embodiments the second process gas may include an inert gas, such as one or more of argon (Ar), neon (Ne), helium (He), or the like, to facilitate delivering the second process gas to the process chamber. In some embodiments, the second process gas may comprise substantially no oxygen (O₂). By providing substantially no oxygen (O₂) the inventors have observed that an etch rate of the photoresist layer 204 may be decreased or suppressed, thereby minimizing consumption of the photoresist layer 204 and allowing the substrate 202 to be etched at a greater depth. As used herein, the use of the term “substantially no oxygen (O₂)” contemplates that the second process gas may have no oxygen present, or trace amounts of oxygen present.

The second process gas may be provided at any flow rate suitable to facilitate etching the substrate 202. For example, in some embodiments, the second process gas may be provided at a flow rate of about 200 to about 900 sccm, or in some embodiments, greater than about 500 sccm. The inventors have observed that by providing the second process gas at such flow rates may improve the etch efficiency of the substrate as compared to conventional etch processes having lower flow rates. The second process gas may be provided to the process chamber for any period of time, for example, such as up to about 3 seconds, or in some embodiments, about 1 second to about 3 seconds.

In some embodiments, the second process gas may be ignited to form plasma to facilitate etching the substrate 202. For example, in some embodiments, an RF and/or DC power may be provided to the process chamber to ignite the first process gas to form and maintain the plasma. In embodiments where an RF power is provided, about 1000 to about 5000 W of RF power may be provided.

In addition, one or more process parameters, for example, such as a temperature or pressure within the process chamber, may be adjusted to facilitate etching the substrate 202 to a desired depth. For example, in some embodiments, the process chamber may be maintained at a pressure of greater than about 160 mTorr, or in some embodiments, up to about 250 mTorr while etching the substrate. The inventors have observed that by maintaining the process chamber at the aforementioned pressure, the etch efficiency of the substrate may be improved, as compared to conventional etch processes utilizing lower pressures. In some embodiments, the process chamber may be maintained at about −10 to about 30 degrees Celsius.

In some embodiments, a bias power may be applied to an electrode or substrate support within the process chamber (e.g., substrate support 340 described below) to facilitate etching the substrate. In such embodiments, about 100 to about 300 W of bias power may be provided to the electrode or substrate support. In some embodiments, the bias power may be provided continuously or, in some embodiments, pulsed. In embodiments where the bias power is pulsed, the bias power may be pulsed at a frequency of about 70 to about 140 Mhz and/or a duty cycle of about 30% to about 80%. By pulsing the bias power, the inventors have observed that an etch rate of the photoresist layer 204 may be decreased or suppressed, thereby minimizing consumption of the photoresist layer 204 and allowing the substrate 202 to be etched at a greater depth.

In some embodiments, each of the first process gas (provided at 104) and the second process gas (provided at 106) may be provided to the process chamber in an alternating manner. For example, in some embodiments, the first process gas may be provided to the process chamber for a first period of time (e.g., up to about 2 seconds) followed by providing the second process gas to the process chamber for a second period of time (e.g., up to about 3 seconds). The first process gas and second process gas may be provided cyclically (e.g., repeatedly providing the first process gas followed by providing the second process gas) and the cycle may be repeated any number of times (e.g., greater than about 100 times) suitable to form the feature 220 to the desired dimensions.

In an exemplary sequence of the method described above, the first process gas may be provided to the process chamber (provided at 104) followed immediately thereafter by the provision of the second process gas to the process chamber (provided at 106) with no intervening steps performed simultaneously or in between. The cycle then repeats with the first process gas provided to the process chamber immediately after the provision of the second process gas to the process chamber with no intervening steps performed simultaneously or in between. The first process gas is provided to the first area (e.g., the center 326 of the substrate 324) via a first set of nozzles (e.g., nozzles 355 described above) and the second process gas is provided to the second area (e.g., the edge 328 of the substrate 324) that is different from the first area, via a second set of nozzles (e.g., nozzles 357) that is different from the first set of nozzles. To provide a desired etch uniformity across the substrate, the second process gas may be provided to the second set of nozzles via a gas ring having a plurality of recursive flow paths (e.g., gas ring 400 described below).

In some embodiments, the first process gas and the second process gas may be provided in the alternating or cyclical manner described above via a gas distribution apparatus configured to provide at least one of selective directional or proportional delivery of the first process gas and the second process gas, such as a fast gas exchange unit. For example, a suitable gas distribution apparatus is described in provisional patent application Ser. No. 15/258,044, titled “GAS DISTRIBUTION APPARATUS FOR DIRECTIONAL AND PROPORTIONAL DELIVERY OF PROCESS GAS TO A PROCESS CHAMBER”. By utilizing such a gas distribution apparatus, the inventors have observed that the first process gas and the second process gas may be provided in a rapid alternating manner at desired areas about the substrate, thereby facilitating control over the uniformity of the polymer containing layer 210 and the etching of the substrate 202 to form the feature 220 having desired dimensions.

FIG. 3 illustrates a sectional side view of a system, such as a process chamber 300, suitable for processing a variety of substrates and accommodating a variety of substrate sizes in accordance with at least portions, such as the etching processes discussed above, of embodiments of the present invention. In some embodiments, the substrate (e.g., substrate 324) may be a round wafer, such as a 200 or 300 mm diameter, or larger, such as 450 mm. The substrate can also be any polygonal, square, rectangular, curved or otherwise non-circular workpiece, such as a polygonal glass substrate used in the fabrication of flat panel displays. The process chamber 300 may be part of an Applied Centura® Silvia™ Etch system, commercially available from Applied Materials, Inc. of Santa Clara, Calif. Other process chambers available from other manufacturers may also be utilized to practice portions of the present invention.

In some embodiments, the process chamber 300 may include a source power 315 and a matching network 317, a bias power 320 and a matching network 321, a chamber 325, a pump 330, a valve 335, a substrate support 340 (e.g., an electrostatic chuck), a chiller 345, a lid 350, one or more gas nozzles 355, 357, and a gas delivery system 302.

In some embodiments, the gas delivery system 302 is located in a housing 305 disposed directly adjacent, such as under, the chamber 325. The gas delivery system 302 selectively couples one or more gas sources located in one or more gas panels 304 to one or more of the gas nozzles 355, 357 to provide process gases to the chamber 325. In some embodiments, the gas delivery system 302 may be configured to provide at least one of selective directional or proportional delivery of one or more process gases (e.g., the first process gas and the second process gas) for example, such as a fast gas exchange unit. The housing 305 is located in close proximity to the chamber 325 to reduce gas transition time when changing gases, minimize gas usage, and minimize gas waste.

The process chamber 300 may further include a lift 327 for raising and lowering the substrate support 340 that supports a substrate 324 in the chamber 325. The chamber 325 further includes a body having a lower liner 322, an upper liner 323, and a door for entry and egress of a substrate 324 (e.g., substrate 202 described above). The valve 335 may be disposed between the pump 330 and the chamber 325 and may be operable to control pressure within the chamber 325. The substrate support 340 may be disposed within the chamber 325. The lid 350 may be disposed on the chamber 325.

The gas nozzles 355, 357 may be disposed about the process chamber 300 in any configuration suitable to provide a desired distribution of process gases. For example, in some embodiments, a first gas nozzle or first set of gas nozzles (e.g., gas nozzle 355) and/or a second gas nozzle or second set of gas nozzles (e.g., gas nozzle 357) may be disposed within the chamber to provide one or more process gases in a desired distribution across the substrate 324. The desired distribution may be any process gas distribution suitable to provide a concentration of one or more process gases to an area proximate a center 326 and/or an edge 328 of the substrate 324. In some embodiments, each of the gas nozzles 355, 357 may comprise a tunable gas nozzle having one or more outlets to selectively direct gas flow from the gas delivery system 302 to the chamber 325. The gas nozzle 355 may be operable to direct gas flow into different areas within the chamber 325, such as the center area and/or the side areas of the chamber 325. In some embodiments, the gas nozzle 355 may include a first outlet that introduces gases from the top of the chamber 325 and a second outlet that introduces gases from the side of the chamber 325 to selectively control the distribution of the gases in the chamber 325.

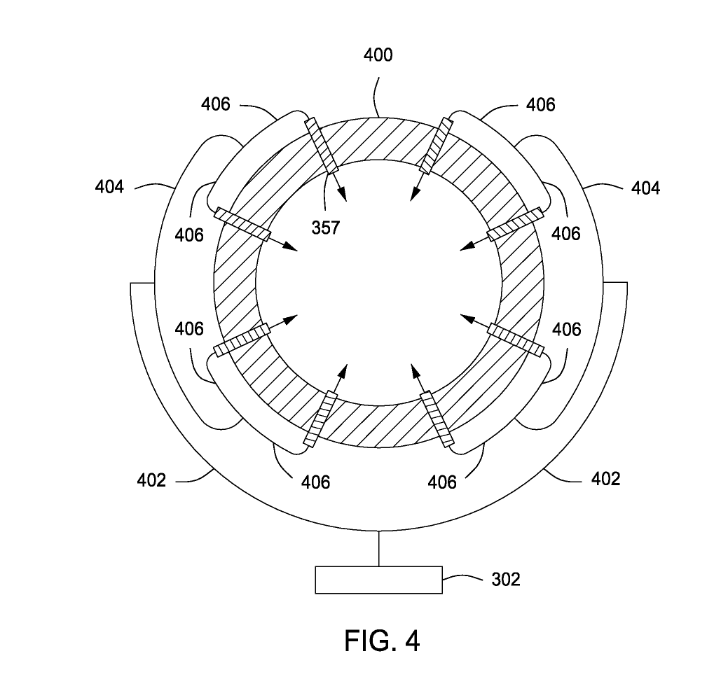

In some embodiments, one or more of the gas nozzles (e.g., gas nozzles 357, 355) may be part of a gas ring 400, for example such as the gas ring 400 shown in FIG. 4. For example, referring to FIG. 4, in some embodiments, the gas delivery system 302 may provide one or more process gases to a plurality of flow paths configure in a recursive pattern, such as shown in the figure. For example, in some embodiments, the gas delivery system 302 may be fluidly coupled to a first set of flow paths 402. Each flow path of the first set of flow paths 402 may be fluidly coupled to a second set of flow paths 404. Each flow path of the second set of flow paths 404 may be fluidly coupled to a third set of flow paths 406, which are then in turn fluidly coupled to respective ones of the gas nozzles (e.g., gas nozzles 357 shown). The inventors have observed that providing the process gases via a gas ring such as shown in FIG. 4 facilitates uniform distribution of the process gases within the process chamber.

Referring back to FIG. 3, the gas delivery system 302 may be used to supply at least two different gas mixtures to the chamber 325 at an instantaneous rate as further described below. In an optional embodiment, the process chamber 300 may include a spectral monitor operable to measure the depth of an etched trench and a deposited film thickness as the trench is being formed in the chamber 325, with the ability to use other spectral features to determine the state of the process chamber 300. The process chamber 300 may be configured to accommodate a variety of substrate sizes, for example a substrate diameter of up to about 300 mm (although larger or smaller sized substrates may be used in process chambers having other configurations).

In some embodiments, the source power 315 for generating and maintaining a plasma is coupled to the chamber 325 via a power generating apparatus enclosed in a housing 311 disposed above the chamber 325. The source power may be an inductively coupled source power. The source power 315 may be operable to generate a radio frequency within a range from about 2 MHz to about 13.5 MHz, having pulsing capabilities, a power within a range from about 10 watts to about 10,000 watts, for example, from about 4,500 watts to about 5,500 watts and may further include a matching network 317. In one example, the source power 315 may be operable to generate a 13 MHz radio frequency having pulsing capabilities. The source power 315 may comprise a dual tunable source so that the radio frequency may be changed during an etching cycle. In some embodiments, the source power 315 may comprise a remote plasma source capable of generating high levels of plasma disassociation that is mountable to the process chamber 300. When using a remote plasma source, the process chamber 300 may further include a plasma distribution plate or series of plates disposed in the chamber 325 to help distribute the plasma to the substrate 324. In some embodiments, the process chamber 300 may include both an in-situ source power and a remote plasma source power, wherein the plasma is generated in a remote plasma chamber using the remote plasma source power and transferred to the chamber 325, wherein the in-situ source power 315 maintains the generated plasma within the chamber 325. In some embodiments, an etching cycle may be performed wherein the power range, i.e. the wattage of the source power 315, may be increased or decreased during the etching cycle. The source power 315 may be pulsed during the etching cycle.

In some embodiments, the bias power 320 for biasing the substrate 324 is coupled to the chamber 325 and the substrate support 340. The bias power 320 may be operable to generate a radio frequency of about 400 KHz having pulsing capabilities, a low power range from about 10 watts to about 2000 watts, for example, from about 900 to about 1800 watts, and may further include a matching network 321. In some embodiments, the bias power 320 may be capable of generating a selectable radio frequency range from about 100 kHz to about 13.56 MHz, from about 100 kHz to about 2 MHz, and from about 400 kHz to about 2 MHz, having pulsing capabilities, a low power range from about 10 watts to about 2,000 watts, and may further include a dynamic matching network or a fixed matching network and a frequency tuner. In some embodiments, an etching cycle may be performed wherein the power range, i.e. the wattage of the bias power 320, may be increased or decreased during the etching cycle.

The bias power 320 may be pulsed during the etching cycle. To pulse the bias power 320, the radio frequency power is switched on and off during the etching cycle. The pulsing frequency of the bias power 320 may range from about 10 Hz to about 1,000 Hz, and may range from about 50 Hz to about 180 Hz. In some embodiments, the switching of the power on and off is uniformly distributed in time throughout the etching cycle. In some embodiments, the timing profile of the pulsing may be varied throughout the etching cycle, and may depend on the composition of the substrate 324. The percentage of time the bias power 320 is switched on, i.e. the duty cycle as described above, is directly related to the pulsing frequency. The bias power frequency and the pulsing frequency may be adjusted depending on the substrate material being processed.

In some embodiments, the chiller 345 may be operable to control the temperature within the chamber 325 and of the substrate 324 located within the chamber 325. The chiller 345 may be located near and coupled to chamber 325. The chiller 345 may include a low temperature chiller, such as a sub-zero point of use thermo-electric chiller, and may further include a direct cooling mechanism for ultra lower temperatures. The chiller 345 is operable to generate temperatures in the range of about −20 degrees to about 80 degrees Celsius, located near the chamber 325 to achieve a faster reaction time, and may include ramping capabilities to allow some level of control to help improve the etch rate. In some embodiments, the chiller 345 is capable of generating temperatures in the range of about −10 degrees to about 60 degrees Celsius and may be located near the chamber 325 to achieve a faster reaction time. In some embodiments, the chiller 345 may be operable to lower the temperature from about −10 degrees Celsius to about −20 degrees Celsius in the chamber 325.

In some embodiments, the process chamber 300 may include an additional cooling mechanism 360 for controlling the temperature of the process chamber 300. The additional cooling mechanism 360 may be positioned on the lid 350 to control the temperature of the lid 350 which may exhibit an increased temperature due to the use of the increased source power. The additional cooling mechanism 360 may comprise one or more high cooling capacity fans.

In some embodiments, the process chamber 300 is operable to maintain a chamber pressure range of about 10 mTorr to about 1,000 mTorr with the pump 330 and the valve 335, which is coupled to the chamber 325. The chamber pressure can be adjusted during the etching cycle to further improve the trench profiles. For example, the chamber pressure may be rapidly decreased or increased when switching from the deposition step to the etch step. The pump 330 may comprise a turbo pump, a 2,600 L/s turbo pump for example, operable to process flows in the range of about 100 sccm to about 1,000 sccm throughout the chamber 325. In conjunction with the pump 330, the valve 335 may comprise a throttling gate valve with a fast reaction time to help control the process flow and the pressure changes. The process chamber 300 may further include a dual manometer to measure the pressure in the chamber 325. In some embodiments, the process chamber 300 is operable to maintain a dynamic pressure in the range of about 10 mTorr to about 250 mTorr, for example, from about 60 to about 150 mTorr, during the etching cycle. Optionally, an automatic throttling gate valve control or a valve with preset control points may be utilized, and the dynamic pressure may be sustained at a set-point while changing flow parameters.

In some embodiments, a controller 354 is provided that includes a central processing unit (CPU) 356, a memory 358, and support circuits 362 for the CPU 356. The controller 354 facilitates control of the components of the process chamber 300 and, as such, of the etch process, as discussed above in further detail. To facilitate control of the process chamber 300, the controller 354 may be one of any form of general-purpose computer processor that can be used in an industrial setting for controlling various chambers and sub-processors. The memory 358, or computer-readable medium, of the CPU 356 may be one or more of readily available memory such as random access memory (RAM), read only memory (ROM), floppy disk, hard disk, or any other form of digital storage, local or remote. The support circuits 362 are coupled to the CPU 356 for supporting the processor in a conventional manner. These circuits include cache, power supplies, clock circuits, input/output circuitry and subsystems, and the like. The inventive methods described herein, or at least portions thereof (e.g., portions performed in the process chamber 300, or portions performed by equipment controlled by the controller 354), may be stored in the memory 358 as a software routine. The software routine may also be stored and/or executed by a second CPU (not shown) that is remotely located from the hardware being controlled by the CPU 356.

Thus, methods for etching a substrate have been disclosed herein. In at least some embodiments, the inventive methods may advantageously provide a method of etching features in a substrate that provides for increased silicon to masking layer etch selectivity as compared to conventionally utilized methods.

While the foregoing is directed to embodiments of the invention, other and further embodiments of the invention may be devised without departing from the basic scope thereof.

1. A method for etching features into a substrate, comprising:
exposing a substrate having a photoresist layer disposed atop the substrate to a first process gas to form a polymer containing layer atop sidewalls and a bottom of a feature formed in the photoresist layer, wherein the first process gas is selectively provided to a first area of the substrate via a first set of gas nozzles disposed within a process chamber; and
exposing the substrate to a second process gas having substantially no oxygen to etch the feature into the substrate, wherein the second process gas is selectively provided to a second area of the substrate via a second set of gas nozzles disposed in the process chamber.

2. The method of claim 1, wherein the first area is proximate at least one of a center of the substrate or an edge of the substrate and wherein the second area is proximate at least one of the center of the substrate or the edge of the substrate.

3. The method of claim 2, wherein at least one of the first process gas or second process gas is sequentially provided proximate the center of the substrate and proximate the edge of the substrate.

4. The method of claim 1, wherein the first process gas is provided for a period of time of up to about 2 seconds and wherein the second process gas is provided for a period of time of up to about 3 seconds.

5. The method of claim 1, wherein the first process gas and the second process gas are alternately provided in a repeating cycle.

6. The method of claim 1, wherein the first process gas comprises one of a fluorine-containing gas, a fluorocarbon-containing gas, or a hydrofluorocarbon-containing gas, and wherein the second process gas comprises a fluorine-containing gas.

7. The method of claim 1, wherein at least one of the first set of gas nozzles or the second set of gas nozzles are coupled to a gas ring, the gas ring having a plurality of flow paths configured in a recursive pattern.

8. The method of claim 7, wherein the plurality of flow paths comprise a first set of flow paths, a second set of flow paths and a third set of flow paths, wherein the first set of flow paths are fluidly coupled to the second set of flow paths, the second set of flow paths are fluidly coupled to a third set of flow paths and the third set of flow paths are fluidly coupled to respective ones of the nozzles.

9. The method of claim 1, wherein the polymer containing layer is formed to a first thickness atop the bottom of the feature and a second thickness atop the sidewalls of the feature, wherein the first thickness is less than the second thickness.

10. The method of claim 1, further comprising:
providing a pulsed bias power to a substrate support while etching the feature into the substrate, wherein the substrate is disposed atop the substrate support.

11. A computer readable medium, having instructions stored thereon that, when executed, cause a method for etching features into a substrate to be performed, the method comprising:
exposing a substrate having a photoresist layer disposed atop the substrate to a first process gas to form a polymer containing layer atop sidewalls and a bottom of a feature formed in the photoresist layer, wherein the first process gas is selectively provided to a first area of the substrate via a first set of gas nozzles disposed within a process chamber; and
exposing the substrate to a second process gas having substantially no oxygen to etch the feature into the substrate, wherein the second process gas is selectively provided to a second area of the substrate via a second set of gas nozzles disposed in the process chamber.

12. The computer readable medium of claim 11, wherein the first area is proximate at least one of a center of the substrate or an edge of the substrate and wherein the second area is proximate at least one of the center of the substrate or the edge of the substrate.

13. The computer readable medium of claim 12, wherein at least one of the first process gas or second process gas is sequentially provided proximate the center of the substrate and proximate the edge of the substrate.

14. The computer readable medium of claim 11, wherein the first process gas is provided for a period of time of up to about 2 seconds and wherein the second process gas is provided for a period of time of up to about 3 seconds.

15. The computer readable medium of claim 11, wherein the first process gas and the second process gas are alternately provided in a repeating cycle.

16. The computer readable medium of claim 11, wherein the first process gas comprises one of a fluorine-containing gas, a fluorocarbon-containing gas or hydrofluorocarbon-containing gas and wherein the second process gas comprises a fluorine-containing gas.

17. The computer readable medium of claim 11, wherein the nozzles are coupled to a gas ring, the gas ring having a plurality of flow paths configured in a recursive pattern.

18. The computer readable medium of claim 17, wherein the plurality of flow paths comprise a first set of flow paths, a second set of flow paths and a third set of flow paths, wherein the first set of flow paths are fluidly coupled to the second set of flow paths, the second set of flow paths are fluidly coupled to a third set of flow paths and the third set of flow paths are fluidly coupled to respective ones of the nozzles.

19. The computer readable medium of claim 11, wherein the polymer containing layer is formed to a first thickness atop the bottom of the feature and a second thickness atop the sidewalls of the feature, and wherein the first thickness is less than the second thickness.

20. The computer readable medium of claim 11, further comprising:
providing a pulsed bias power to a substrate support while etching the feature into the substrate, wherein the substrate is disposed atop the substrate support.
